(19) United States
(12) Patent Application Publication
(10) Pub. No.: US 2026/0279724 A1
(43) Pub. Date: Sep. 17, 2026

(54) CHARGED PARTICLE BEAM WRITING METHOD, CHARGED PARTICLE BEAM WRITING APPARATUS AND COMPUTER-READABLE RECORDING MEDIUM

(71) Applicant: NuFlare Technology, Inc., Yokohama-shi (JP)

(72) Inventors: Haruyuki NOMURA, Yokohama-shi (JP); Takuro CHIDA, Nerima-ku (JP)

(73) Assignee: NuFlare Technology, Inc., Yokohama-shi (JP)

(21) Appl. No.: 19/431,472

(22) Filed: Dec. 23, 2025

(30) Foreign Application Priority Data
Mar. 11, 2025 (JP) 2025-038624

(51) Int. Cl. H01J 37/302; H01J 37/317

(52) U.S. Cl. CPC H01J 37/3026; H01J 37/3177; H01J 2237/31764; H01J 2237/31769

(57) ABSTRACT

In one embodiment, a charged particle beam writing method is provided for writing a pattern on a substrate using a charged particle beam. The charged particle beam writing method includes virtually dividing a writing region of the substrate into a plurality of first mesh regions having a first mesh size, calculating a pattern area density of each of the first mesh regions to create a first area density map, sampling the first area density map with second mesh regions having a second mesh size smaller than the first mesh size, and creating a second area density map that defines a pattern area density for each of the second mesh regions, calculating an irradiation amount for each of the second mesh regions using the second area density map, and irradiating the substrate with the charged particle beam in the calculated irradiation amount.

### CROSS REFERENCE TO RELATED APPLICATION

This application is based upon and claims benefit of priority from the Japanese Patent Application No. 2025-38624, filed on Mar. 11, 2025, the entire contents of which are incorporated herein by reference.

### FIELD

The present invention relates to a charged particle beam writing method, a charged particle beam writing apparatus and a computer-readable recording medium.

### BACKGROUND

As LSI circuits are increasing in density, the required linewidths of circuits included in semiconductor devices become finer year by year. To form a desired circuit pattern on a semiconductor device, a method is employed in which a high-precision original pattern formed on quartz is transferred to a wafer in a reduced manner by using a reduced-projection exposure apparatus. The high-precision original pattern is written on a photomask by an electron-beam writing apparatus.

A writing apparatus using multiple beams enables irradiation with a large number of beams at once as compared with writing with a single electron beam, and thereby significantly improve throughput. Examples of such multi-beam writing apparatuses include a multi-beam writing apparatus using a blanking aperture array substrate (blanking plate). In such a multi-beam writing apparatus, for example, an electron beam emitted from an electron source passes through a shaping aperture array substrate having multiple apertures, thus forming multiple beams (multiple electron beams). A blanking aperture array substrate is arranged downstream of the shaping aperture array substrate. The blanking aperture array substrate includes pairs of electrodes for individually deflecting the beams, and has an aperture for beam passage between each pair of electrodes. One of the paired electrodes (blanker) is held at ground potential, and the other electrode is switched between the ground potential and a potential other than the ground potential, thus achieving blanking deflection of an electron beam that is to pass through the blanker. In the multi-beam writing apparatus, an optical column is configured such that an electron beam deflected by the blankers are blocked and turned off, while electron beams that are not deflected are irradiated onto a sample as on-beams.

In order to increase the productivity of pattern writing by reducing waiting time, it has been studied to use pattern data, which has been prepared for a certain multi-beam writing apparatus, in multi-beam writing apparatuses of different generations or single-beam writing apparatuses.

However, since performance such as resolution differs between a multi-beam writing apparatus for which the pattern data was prepared and a multi-beam writing apparatus of a different generation or a single beam writing apparatus, when the same pattern data is used, there arises a problem in that the line width and shape of the written pattern vary.

### BRIEF DESCRIPTION OF THE DRAWINGS

FIG. 1 is a schematic view of a multi-charged particle beam writing apparatus according to an embodiment of the present invention.

FIG. 2 is a view illustrating a configuration example of a shaping aperture array substrate.

FIG. 3 is a view for explaining an example of a writing operation.

FIG. 4 is a view illustrating an example of an irradiation region and writing target pixels of a multi-beam.

FIG. 5 is a graph illustrating an example of CD linearity of a writing apparatus.

FIG. 6 is a graph illustrating an example of dose latitude of a writing apparatus.

FIG. 7 is a view illustrating an example of a rasterization process based on individual beam size, and an example of a coarse rasterization process followed by upsampling.

FIG. 8 is a graph illustrating a simulation result of CD linearity for each mesh size of the rasterization process.

FIG. 9 is a flowchart for explaining a writing method according to the embodiment.

FIG. 10 is a graph illustrating an example of determining the mesh size for the rasterization process.

FIG. 11 is a view illustrating an example of an area density map.

FIG. 12 is a view illustrating an example of an area density map in different phases.

FIG. 13 is a view for explaining a method of calculating a pattern area density of a second mesh region.

FIG. 14A is a view illustrating a design pattern, FIG. 14B is a view illustrating a finished pattern, and FIG. 14C and FIG. 14D are views illustrating a feature value.

### DETAILED DESCRIPTION

In one embodiment, a charged particle beam writing method is provided for writing a pattern on a substrate using a charged particle beam. The charged particle beam writing method includes virtually dividing a writing region of the substrate into a plurality of first mesh regions having a first mesh size, calculating a pattern area density of each of the first mesh regions to create a first area density map, sampling the first area density map with second mesh regions having a second mesh size smaller than the first mesh size, and creating a second area density map that defines a pattern area density for each of the second mesh regions, calculating an irradiation amount for each of the second mesh regions using the second area density map, and irradiating the substrate with the charged particle beam in the calculated irradiation amount.

Embodiments of the present invention will be described below with reference to the drawings. In the embodiments, a configuration using an electron beam as an example of a charged particle beam will be described. However, the charged particle beam is not limited to an electron beam and may be an ion beam or the like.

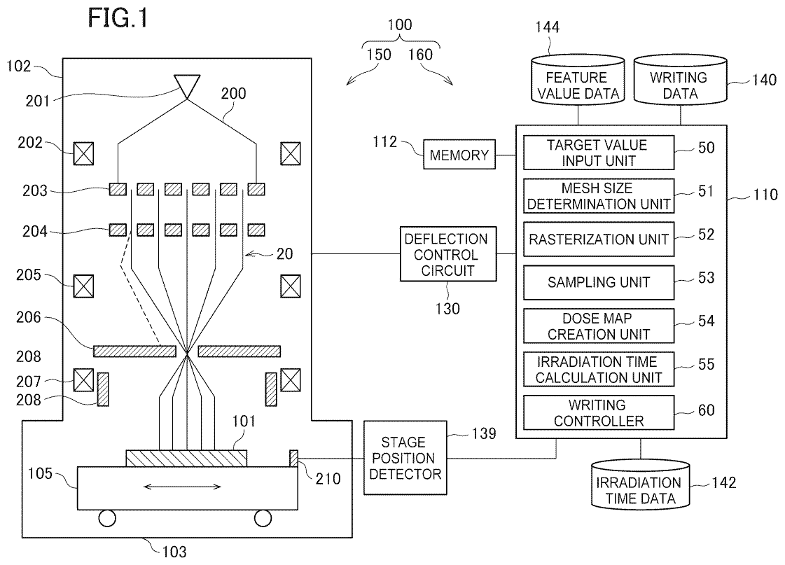

FIG. 1 is a schematic configuration view of a writing apparatus according to an embodiment. As illustrated in FIG. 1, a writing apparatus 100 includes a writing unit 150 and a controller 160. The writing apparatus 100 is an example of a multi-charged particle beam writing apparatus.

The writing unit 150 includes an electron optical column 102 and a writing chamber 103. In the electron optical column 102, an electron source 201, an illumination lens 202, a shaping aperture array substrate 203, a blanking aperture array substrate 204, a reduction lens 205, a limiting aperture member 206, an objective lens 207, and a deflector 208 are disposed.

A continuously movable XY stage 105 is disposed in the writing chamber 103. At the time of writing, a substrate 101 as a writing target is disposed on the XY stage 105. The substrate 101 is e.g., a mask blank which is coated with resist and on which nothing has been written. On the XY stage 105, a mirror 210 for measuring the position of the XY stage 105 is disposed.

The controller 160 includes a control computer 110, a memory 112, a deflection control circuit 130, a stage position detector 139, and storage devices 140, 142, 144 such as a magnetic disk drive. These are connected to each other via a bus. Pattern data (writing data) defining the layout of a figure pattern to be written is input to the storage device 140 from the outside, and stored therein.

The control computer 110 includes a target value input unit 50, a mesh size determination unit 51, a rasterization unit 52, a sampling unit 53, a dose map creation unit 54, an irradiation time calculation unit 55 and a writing controller 60. These functions may be implemented by hardware such as an electric circuit, or implemented by software. When the functions are implemented by software, a program implementing at least part of the functions may be stored in a recording medium, and the program may be read and executed by a computer having a CPU. The recording medium storing the program is not limited to a detachable one such as a magnetic disk or an optical disc, and may be a fixed recording medium such as a hard disk drive or a memory. Information such as a calculation result in the control computer 110 is stored in the memory 112 each time.

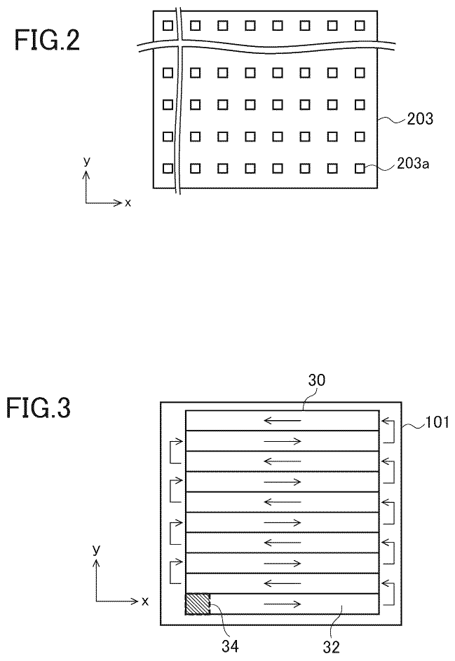

FIG. 2 is a conceptual view illustrating a configuration example of the shaping aperture array substrate 203. The shaping aperture array substrate 203 includes a plurality of openings 203a arranged in a matrix at a predetermined pitch in the vertical and horizontal directions. For example, 512×512 openings 203a are formed vertically and horizontally (x, y direction). Each opening 203a is formed in a rectangular or circular shape with the same dimensions.

Part of an electron beam 200 emitted from the electron source 201 passes through the plurality of openings 203a, thereby forming a multi-beam 20 including a plurality of individual beams.

In the blanking aperture array substrate 204, passage holes (openings) through which respective individual beams pass are formed at positions corresponding to the openings 203a of the shaping aperture array substrate 203 illustrated in FIG. 2. A set (a blanker, i.e., a blanking deflector) of electrodes for blanking deflection is disposed across each passage hole. One of two electrodes receives an applied deflection voltage based on a control signal from the deflection control circuit 130, and the other electrode is grounded.

An individual beam passing through each passage hole is independently deflected by a blanker, and blanking control is performed. In this manner, a plurality of blankers perform blanking deflection on corresponding individual beams, respectively.

FIG. 3 is a conceptual view for explaining an example of a writing operation. For example, as illustrated in FIG. 3, a writing region 30 of the substrate 101 is virtually divided into a plurality of stripe regions 32 in y direction with a predetermined width.

First, the XY stage 105 is moved, and an irradiation region 34 which can be irradiated with the multi-beam 20 at one time is adjusted to be located at the left end or a further left position of the first stripe region 32, then writing is started. When writing is performed on the first stripe region 32, writing proceeds relatively in +x direction, for example, by moving the XY stage 105 in −x direction. The XY stage 105 is, for example, continuously moved at a predetermined speed.

After writing on the first stripe region 32 is completed, the stage position is moved in-y direction, and the irradiation region 34 is adjusted to be located relatively in y direction at the right end or a further right position of the second stripe region 32. This time, writing is similarly performed in −x direction by moving the XY stage 105, for example, in +x direction.

In the third stripe region 32, writing is performed in +x direction, and in the fourth stripe region 32, writing is performed in −x direction. In this manner, the writing time can be reduced by performing writing while alternately changing the direction. However, writing is not necessarily performed while alternately changing the direction, and writing may be performed in the same direction on each stripe region 32. In one shot, a plurality of shot patterns at most equal in number to the openings 203a are formed at one time by the multi-beam which is formed by passing the beam through the openings 203a of the shaping aperture array substrate 203.

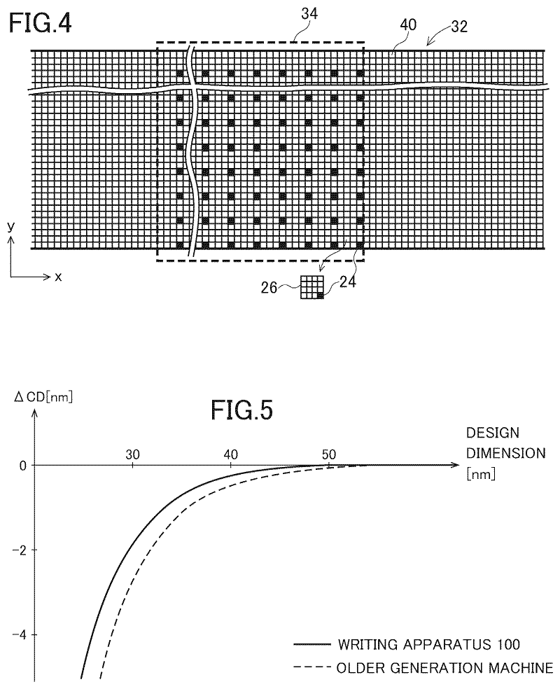

FIG. 4 is a view illustrating an example of an irradiation region and writing target pixels of the multi-beam. In FIG. 4, the stripe region 32 is divided into a plurality of mesh-shaped regions 40 by, for example, the beam size of individual beam. Each mesh region 40 serves as a writing pixel region (writing position). The example of FIG. 4 shows the case where the writing region of the substrate 101 is divided into a plurality of stripe regions 32 e.g., in y direction by the size (shot size) of the irradiation region 34 which can be irradiated with the multi-beam 20 at one time. Note that the width of each stripe region 32 is not limited to this, and may be the size that is e.g., n times (n is an integer greater than or equal to 1) the irradiation region 34.

In the irradiation region 34, a plurality of pixels 24 (beam irradiation positions) that can be irradiated at one time by the multi-beam 20 are shown. In other words, the pitch between adjacent pixels 24 is the pitch between the beams of the multi-beam. In the example of FIG. 4, one subpitch region 26 is formed by the square region that is surrounded by adjacent four pixels 24, and that includes one of the four pixels 24. FIG. 4 shows the case where each subpitch region 26 is formed by 4×4 pixels.

Next, the operation of the writing unit 150 will be described. The electron beam 200 emitted from the electron source 201 (emitter) illuminates the entire shaping aperture array substrate 203 substantially perpendicularly by the illumination lens 202. The electron beam 200 passes through the plurality of openings 203a of the shaping aperture array substrate 203, thereby forming the multi-beam 20 including a plurality of individual beams. The beam array shape of the multi-beam 20 is e.g., rectangular. The multi-beam 20 passes through corresponding blankers of the blanking aperture array substrate 204. The blankers individually deflect the beam so that the beam is set beam-ON only for a calculated writing time (irradiation time), and is set beam-OFF for the time other than the writing time.

The multi-beam 20 which has passed through the blanking aperture array substrate 204 is reduced by the reduction lens 205, and travels to the central opening formed in the limiting aperture member 206. An electron beam deflected to be beam-OFF by a blanker of the blanking aperture array substrate 204 is displaced from the central opening of the limiting aperture member 206 and blocked by the limiting aperture member 206. In contrast, a beam (deflected to be beam-ON) not deflected by any blanker of the blanking aperture array substrate 204 passes through the central opening of the limiting aperture member 206.

The beam for one shot is formed by the beam which has passed through the limiting aperture member 206 since beam-ON until beam-OFF is achieved. The multi-beam 20 which has passed through the limiting aperture member 206 is focused by the objective lens 207 to form a pattern image with a desired reduction ratio, and the beams (the entire multi-beam 20) are collectively deflected by the deflector 208 in the same direction, then emitted to respective writing positions (irradiation positions) on the substrate 101.

When the XY stage 105 is moving continuously, tracking control is performed by the deflector 208 so that the writing positions (irradiation positions) of the beams follow the movement of the XY stage 105. A laser is emitted from the stage position detector 139 to the mirror 210 on the XY stage 105, and the position of the XY stage 105 is measured using reflected light. The multi-beams emitted at one time are ideally arranged with the pitch which is the product of the arrangement pitch of the plurality of openings 203a of the shaping aperture array substrate 203 and the above-mentioned desired reduction ratio.

The writing apparatus 100 emits a multi-beam serving as a shot beam to a sequentially shifted writing position while following the movement of the XY stage 105 during the tracking operation each time.

In order to improve the productivity of photomask, use of the writing apparatus 100 as well as a multi-beam writing apparatus different from the writing apparatus 100 in generation may be required. However, the feature value of writing pattern, such as CD linearity and dose latitude differs between writing apparatuses in different generations, thus when the same pattern data is used, finished dimension of writing pattern varies.

The CD linearity is the difference between design dimension and finished dimension with respect to the design dimension, and the smaller the design dimension, the larger the difference. The degree of change in the difference with respect to the design dimension varies between the writing apparatuses in different generations.

FIG. 5 illustrates an example of CD linearity of the writing apparatus 100, and a multi-beam writing apparatus (hereinafter called older generation machine) older in generation than the writing apparatus 100. For example, the older generation machine has a larger beam size of individual beam and a lower resolution than those of the writing apparatus 100. In FIG. 5, the horizontal axis corresponds to design dimension (line width), and the vertical axis corresponds to the difference (Δ CD) between the design dimension and the finished dimension.

As illustrated in FIG. 5, the smaller the design dimension, the larger the difference. The older generation machine exhibits a greater variation in the difference compared to the writing apparatus 100.

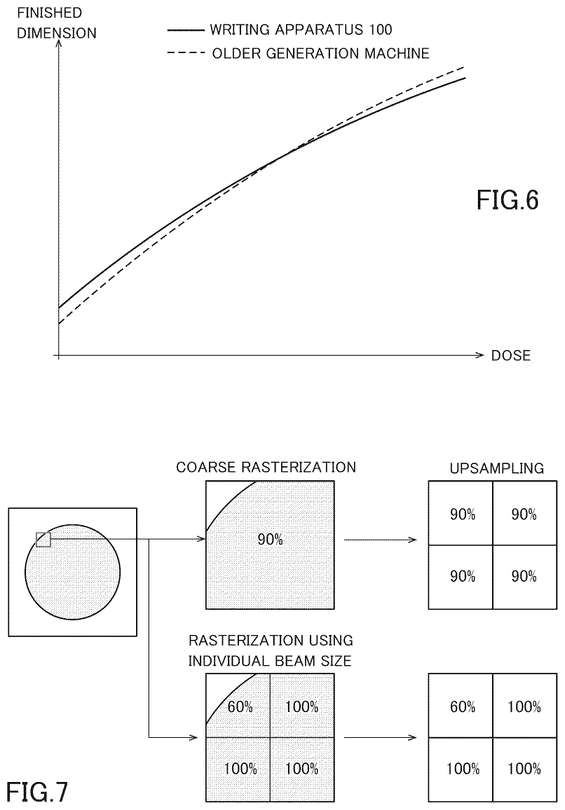

The dose latitude is the ratio of the amount of change in the pattern dimension to the amount of change in the beam irradiation amount. FIG. 6 illustrates an example of dose latitude of the writing apparatus 100 and the older generation machine. In FIG. 6, the horizontal axis corresponds to dose amount, and the vertical axis corresponds to finished dimension.

As illustrated in FIG. 6, the older generation machine has a larger change in the finished dimension with respect to the change in the dose amount than that of the writing apparatus 100.

As described above, the feature value of writing pattern, such as CD linearity and dose latitude is different between the writing apparatus 100 and the older generation machine. The writing apparatus 100 according to the present embodiment performs writing with the feature values matched to those of the older generation machine, and is able to form a pattern having the same (or substantially the same) finished dimension.

In a normal writing process, the writing apparatus 100 reads pattern data from the storage device 140, and for each mesh region 40 corresponding to the beam size of an individual beam, calculates a pattern area density in the mesh region 40 to generate an area density map, that is, performs so-called the rasterization process. The dose amount (incident irradiation amount) for each mesh region 40 is calculated using the pattern area density defined in the area density map.

Meanwhile, in the writing process with the feature values matched to those of the older generation machine, the writing apparatus 100 first virtually divides the writing region 30 into first mesh regions each larger in size than the mesh region 40, and for each of the first mesh regions, calculates a pattern area density in the first mesh region to generate a first area density map. In other words, a rasterization process coarser than a normal writing process is performed.

Subsequently, the writing apparatus 100 generates a second area density map to which the first area density map is upsampled on second mesh regions (mesh regions 40) in the beam size of individual beam. The dose amount for each of the second mesh regions (mesh regions 40) is calculated using the pattern area density defined in the second area density map.

FIG. 7 illustrates an example of a rasterization process using the beam size of individual beam, and an example of a coarse rasterization process that is subsequently upsampled.

The inventors have found that feature values can be altered by changing the mesh size when a coarse rasterization process is performed. Thus, for example, a sampling process can be applied to the data which has undergone the rasterization process with coarse meshes by an old-version apparatus to be used in the old-version apparatus so that writing can be performed using the above-described method by a new-version apparatus without increasing the amount of calculation.

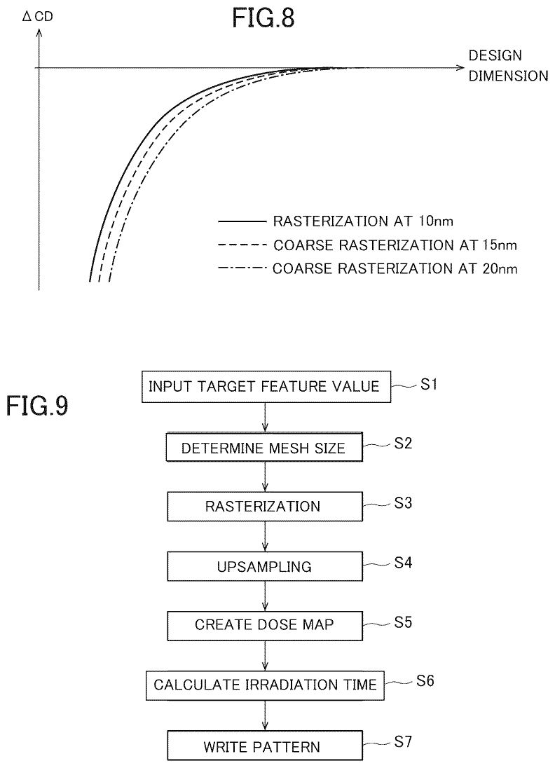

FIG. 8 illustrates a simulation result of CD linearity when writing is performed using the second area density map which is upsampled with a mesh size of 10 nm after a coarse rasterization process with a mesh size of 15 nm is performed, and a simulation result of CD linearity when writing is performed using the second area density map which is upsampled with a mesh size of 10 nm after a coarse rasterization process with a mesh size of 20 nm is performed. FIG. 8 also illustrates a simulation result of CD linearity when as in the normal writing process, a rasterization process is performed with a mesh size of 10 nm to create an area density map, and writing is performed. It is seen that CD linearity is altered by changing the mesh size when a coarse rasterization process is performed.

The feature value data such as CD linearity and dose latitude for each mesh size during a coarse rasterization process is determined in advance by a simulation or actual writing, and stored in the storage device 144.

Next, the writing method according to the embodiment will be described with reference to the flowchart illustrated in FIG. 9.

The target value input unit 50 receives an input of a feature value of an older generation machine as a target value (step S1). For example, data on the CD linearity of the older generation machine is input.

The mesh size determination unit 51 compares the target value with the feature value data stored in the storage device 144, and determines the mesh size (the first mesh size) to be used in the coarse rasterization process (step S2).

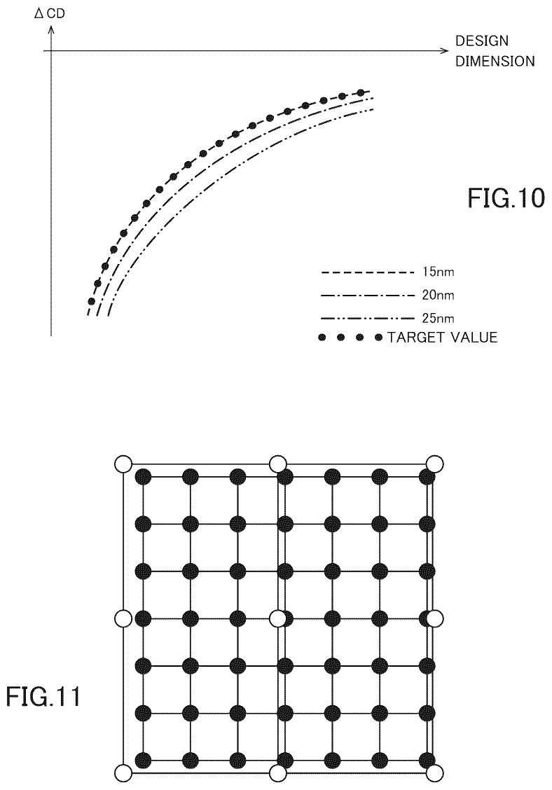

For example, as illustrated in FIG. 10, the mesh size determination unit 51 compares the CD linearity (target value) of an old generation machine with the CD linearity for each mesh size, and selects a mesh size which gives the best approximation. In the example illustrated in FIG. 10, it is seen that a coarse rasterization process should be performed with a mesh size of 15 nm.

The rasterization unit 52 reads pattern data from the storage device 140 and performs a rasterization process using the first mesh size determined in step S2. For each first mesh region of the first mesh size, the rasterization unit 52 calculates the pattern area density within the region and creates a first area density map (step S3). The first area density map is stored in the memory 112.

The sampling unit 53 calculates the pattern area density for each second mesh region corresponding to the beam size (the second mesh size) of each individual beam, based on the first area density map, and creates a second area density map by upsampling the first area density map (step S4). For example, the second area density map is created by upsampling, with a mesh size of 10 nm, the first area density map with a mesh size of 15 nm.

FIG. 11 is a view for explaining an example of creating the second area density map from the first area density map. Each white circle ○ in FIG. 11 indicates the center of a first mesh region, and the value of the pattern area density is defined in the first area density map. Each black circle ● indicates the center of a second mesh region, and the value of the pattern area density is defined in the second area density map.

The pattern area density of the second mesh region may be determined by using the pattern area density of the nearest first mesh region, or determined by interpolation of the pattern area densities of four proximity first mesh regions.

The dose map creation unit 54 creates a dose map that defines the incidence irradiation amount for each second mesh region (step S5). The dose map creation unit 54 virtually divides the writing region (e.g., the stripe region 32) into a plurality of proximity mesh-shaped regions (mesh regions for proximity effect correction calculation) by a predetermined size. It is preferable that the size of proximity mesh region be set to approximately 1/10 of the extent of influence of the proximity effect, for example, approximately 1 μm. The dose map creation unit 54 reads pattern data from the storage device 140, and for each proximity mesh region, calculates a pattern area density ρ in the proximity mesh region.

Next, for each proximity mesh region, the dose map creation unit 54 calculates a proximity effect correction irradiation coefficient Dp(x) for correcting the proximity effect. The proximity effect correction irradiation coefficient Dp(x) can be defined by a threshold value model for proximity effect correction similar to a conventional technique, the threshold value model using a backscatter coefficient η, an irradiation amount threshold value Dth of the threshold value model, a pattern area density ρ, and a distribution function g(x).

Next, for each second mesh region, the dose map creation unit 54 calculates an incident irradiation amount D (dose amount) for irradiating with the second mesh region by multiplying a preset reference irradiation amount Dbase by the proximity effect correction irradiation coefficient Dp, and the pattern area density ρ′ defined in the second area density map. The reference irradiation amount Dbase can be defined, for example, by Dth/(½+η).

The dose map creation unit 54 creates a dose map that defines the incident irradiation amount D for each second mesh region stripe by stripe. The created dose map is stored in e.g., the storage device 142.

The irradiation time calculation unit 55 refers to the dose map, and for each second mesh region, calculates an irradiation time t corresponding to the incident irradiation amount D (step S6). The irradiation time t is calculated by dividing the incident irradiation amount D by a current density. The irradiation time t is calculated as a value within a maximum irradiation time for which irradiation can be made by one shot of the multi-beam 20. The irradiation time data is stored in the storage device 142.

In the writing step (step S7), the writing controller 60 rearranges the irradiation time data in the shot order along the writing sequence. The irradiation time data is then transferred to the deflection control circuit 130 in the shot order. The deflection control circuit 130 outputs a blanking control signal to the blanking aperture array substrate 204 in the shot order, and outputs a deflection control signal to the deflector 208 in the shot order. The writing unit 150 writes a pattern on the substrate 101 using a multi-beam in the irradiation amount calculated for each second mesh region.

The pattern written on the substrate 101 has substantially the same feature value as that of the pattern written by an old generation machine, and (substantially) the same photomask can be produced by the writing apparatus 100 and the old generation machine, thus the productivity can be improved.

In the above embodiment, an example of creating the second area density map from one sheet of the first area density map has been described; however, the second area density map may be created using multiple sheets of the first area density map with the phase shifted for a figure pattern.

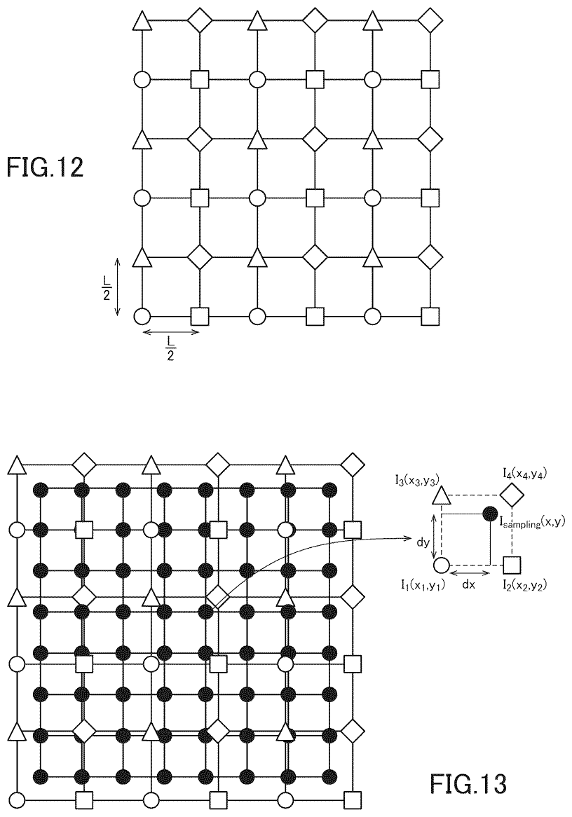

For example, as illustrated in FIG. 12, the rasterization unit 52 creates four sheets of the first area density map with the phase of the first mesh region shifted by L/2 in x direction and/or y direction, where L is the mesh size of the first mesh region. In FIG. 12, •, Δ, □, ⋄ indicate the respective centers of the mesh regions of the four sheets of the first area density map, and the value of each pattern area density is defined.

As illustrated in FIG. 13, the pattern area density of a second mesh region is determined by bilinear interpolation approximation of the values of the pattern area densities of four proximity first mesh regions. The four proximity first mesh regions refer to the first mesh regions each nearest to the second mesh region which is a calculation target in each of four sheets of the first area density map. As viewed from the second mesh region which is a calculation target, the distance in x direction, and the distance in y direction from the four proximity first mesh regions are both L/2 or less.

Let I₁(x₁, y₁), I₂(x₂, y₂), I₃(x₃, y₃), I₄(x₄, y₄) be the pattern area densities of the four proximity first mesh regions, then the sampling unit 53 calculates a pattern area density I_{sampling}(x, y) of the second mesh region as a calculation target using the following expression.

$${I}_{sampling} ( x , y ) = \{ ( L / 2 - dx ) ( L / 2 - dy ) {I}_{1} ( {x}_{1} , {y}_{1} ) + d x ( L / 2 - dy ) {I}_{2} ( {x}_{2} , {y}_{2} ) + ( L / 2 - dx ) {dyI}_{3} ( {x}_{3} , {y}_{3} ) + d {xdyI}_{4} ( {x}_{4} , {y}_{4} ) \} / {( L / 2 )}^{2}$$

In this manner, the second area density map is created from multiple first area density maps in different phases, and writing is performing, thus it is possible to use pattern information of sampling interval of rasterized meshes which are finer than when a single first area density map is used, therefore, deterioration of the pattern dimension accuracy due to aliasing can be reduced.

Calculation of the pattern area density of the second mesh region is not limited to the approximation by bilinear interpolation, and approximation may be made by nearest-neighbor interpolation or bicubic interpolation.

In the above embodiment, the feature value of writing pattern is not limited to CD linearity and dose latitude, and may also be evaluated using Square Loss Area or Corner rounding.

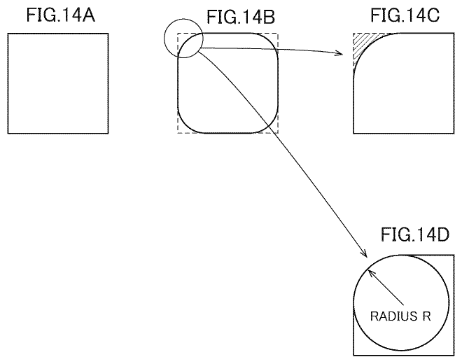

When a rectangular pattern as illustrated in FIG. 14A is written, the finished pattern has a shape with each corner rounded as illustrated in FIG. 14B. As shown by the shaded portion of FIG. 14C, the area (or the area rate of a lost portion with respect to a design value) that is lost by rounding a corner is called Square Loss Area.

As illustrated in FIG. 14D, the value of the degree of rounding of the corner determined using curvature radius R is called Corner rounding.

The target value as an input received by the target value input unit 50 is not limited to the feature value of an old generation multi-beam writing apparatus, and may be the feature value of a single beam writing apparatus.

The above embodiments can be applied not only to a multi-beam writing apparatus but also to a single beam writing apparatus using a raster beam.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charged particle beam writing method for writing a pattern on a substrate using a charged particle beam, the charged particle beam writing method comprising:
virtually dividing a writing region of the substrate into a plurality of first mesh regions having a first mesh size;
calculating a pattern area density of each of the first mesh regions to create a first area density map;
sampling the first area density map with second mesh regions having a second mesh size smaller than the first mesh size, and creating a second area density map that defines a pattern area density for each of the second mesh regions;
calculating an irradiation amount for each of the second mesh regions using the second area density map; and
irradiating the substrate with the charged particle beam in the calculated irradiation amount.

2. The charged particle beam writing method according to claim 1,
wherein the first mesh size is determined based on a feature value of a writing pattern of another writing apparatus.

3. The charged particle beam writing method according to claim 1,
wherein a plurality of first area density maps in different phases are created, and
a pattern area density of each of the second mesh regions is calculated by interpolation approximation of pattern area densities defined in each of the plurality of first area density maps.

4. A charged particle beam writing apparatus for writing a pattern on a substrate using a charged particle beam, the charged particle beam writing apparatus comprising:
a rasterization unit that virtually divides a writing region of the substrate into a plurality of first mesh regions having a first mesh size, and calculates a pattern area density of each of the first mesh regions to create a first area density map;
a sampling unit that samples the first area density map with second mesh regions having a second mesh size smaller than the first mesh size, and creates a second area density map defining a pattern area density for each of the second mesh regions;
a calculation unit that calculates an irradiation amount for each of the second mesh regions using the second area density map; and
a writing unit that irradiates the substrate with the charged particle beam in the calculated irradiation amount.

5. A computer readable recording medium storing a program causing a computer to execute a process comprising:
a step of virtually dividing a writing region of a substrate into a plurality of first mesh regions having a first mesh size, the substrate being written with a pattern using a charged particle beam;
a step of calculating a pattern area density of each of the first mesh regions to create a first area density map;
a step of sampling the first area density map with second mesh regions having a second mesh size smaller than the first mesh size, and creating a second area density map defining a pattern area density for each of the second mesh regions;
a step of calculating an irradiation amount for each of the second mesh regions using the second area density map; and
a step of controlling a writing unit to irradiate the substrate with the charged particle beam in the calculated irradiation amount.
